(19) United States
(12) Patent Application Publication
(10) Pub. No.: US 2026/0120753 A1
(43) Pub. Date: Apr. 30, 2026

(54) DRAM-BASED ONE TIME PROGRAMMING MEMORY

(71) Applicant: AP MEMORY TECHNOLOGY CORPORATION, HSINCHU COUNTY (TW)

(72) Inventor: WENLIANG CHEN, HSINCHU COUNTY (TW)

(21) Appl. No.: 19/224,951

(22) Filed: Jun. 2, 2025

Related U.S. Application Data
(60) Provisional application No. 63/711,553, filed on Oct. 24, 2024.

(51) Int. Cl. G11C 11/4096

(52) U.S. Cl. CPC G11C 11/4096

(57) ABSTRACT

A programming method of a DRAM (dynamic random-access memory)-based one time programming (OTP) memory device is provided. A selected word line (WL) of a selected page is turned on. A sensing circuit is turned on to sense a first data set in the selected page into the sensing circuit. A cell plate voltage (V_{PLT}) is set to a high voltage and the selected page is programmed. The V_{PLT} is lowered, and the selected WL of the selected page is turned off.

### PRIORITY CLAIM AND CROSS-REFERENCE

This application claims priority to U.S. Provisional Application No. 63/711,553 filed October 24, 2024, the disclosures of all of which are hereby incorporated by reference in its their entirety.

### BACKGROUND

Computer systems generally contain non-volatile memory used for storing instruction codes and data, and volatile memory used as working memory. DRAM (dynamic random-access memory) is the primary form of the working memory. In a conventional computer system, the volatile memory and the non-volatile memory are formed and configured separately, and their use scenarios are not inter-changeable. As more and more new applications emerge, e.g., AI inference, machine learning, or the like, the data of such applications need to be stored in DRAM for quick access with low power consumption. Further, these data also need to be stored permanently in the computer system. Therefore, there is an increasing need to improve the DRAM configuration to address the demands of the quick and low-power access requirements while maintaining data permanently.

### SUMMARY

According to one aspect of the present disclosure, a programming method of a DRAM (dynamic random-access memory)-based one time programming (OTP) memory device includes: turning on a selected word line (WL) of a selected page; turning on sensing circuit to sense a first data set in the selected page into the sensing circuit; setting a plate voltage (V_{PLT}) to a high voltage and programming the selected page; lowering the V_{PLT}; and turning off the selected WL of the selected page.

According to another aspect of the present disclosure, a reading method of a DRAM-based one time programming (OTP) memory device includes: setting a plate voltage (V_{PLT}) to a first voltage; turning on a selected word line (WL) of a selected page; turning on a sensing circuit; writing a first logic state corresponding to the first voltage into a plurality of memory cells of the selected page; turning off the selected WL of the selected page and the sensing circuit; turning on the selected WL of the selected page after a predetermined time; and turning on the sensing circuit to sense at least one second logic state of the memory cell in the plurality of memory cells in the selected page.

According to yet another aspect of the present disclosure, a testing and correction method of a DRAM-based one time programming (OTP) memory device includes performing a pre-shipment testing before the OTP programming operation based on a normal DRAM function test.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A and 1B are schematic diagrams of a memory device, in accordance with various embodiments of the present disclosure.

FIG. 2 is a schematic diagram of a one-time-programming (OTP) programming operation on a memory cell, in accordance with some embodiments of the present disclosure.

FIG. 3 is a schematic diagram of an OTP memory device, in accordance with various embodiments of the present disclosure.

FIG. 4A is a schematic timing diagram of a method of programming a one-time-programming (OTP) memory cell, in accordance with some embodiments of the present disclosure.

FIGS. 4B and 4C are schematic flowcharts showing methods of programming an OTP memory cell, in accordance with various embodiments of the present disclosure.

FIGS. 5A and 5B are schematic timing diagrams of a method of reading one-time-programming (OTP) memory cells, in accordance with various embodiments of the present disclosure.

FIGS. 5C and 5D are schematic flowcharts showing methods of reading an OTP memory cell, in accordance with various embodiments of the present disclosure.

FIGS. 6A is a schematic diagram of an OTP memory device, in accordance with various embodiments of the present disclosure.

FIG. 6B is a schematic diagram of a comparator of a memory device, in accordance with various embodiments of the present disclosure.

FIGS. 7A and 7B are schematic flowcharts showing methods of reading an OTP memory cell, in accordance with various embodiments of the present disclosure.

FIG. 8 is a schematic flowchart showing a method of forming and testing a memory device, in accordance with various embodiments of the present disclosure.

### DETAILED DESCRIPTION

The following disclosure provides many different embodiments, or examples, for implementing different features of the provided subject matter. Specific examples of components and arrangements are described in the present disclosure in order to facilitate understanding of the invention. Such examples are merely provided to aid in understanding and are not intended to limit the present disclosure. For example, the formation of a first feature over or on a second feature as described herein may include embodiments in which the first and second features are formed in direct contact, and may also include embodiments in which additional features are formed between the first and second features, such that the first and second features are not in direct contact. In addition, the present disclosure may repeat reference numerals and/or letters in the various examples. Such repetition is for the purpose of simplicity and clarity and does not necessarily indicate a relationship between the various embodiments and/or configurations described.

Further, spatially relative terms, such as “beneath,” “below,” “lower,” “above,” “upper” and the like, may be used herein for ease of description to describe one element or feature’s relationship to another element(s) or feature(s) as illustrated in the figures. Such spatially relative terms are intended to encompass different orientations of the device in use or operation in addition to the orientation depicted in the figures. The apparatus may be otherwise oriented (for example, rotated 90 degrees from the depicted orientation) and the spatially relative descriptors used herein should accordingly be interpreted as including other orientations.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “approximately” or “substantially” may mean within some small percentage of a given value or range. Alternatively, the terms “about,” “approximately” or “substantially” mean within an acceptable standard error of the value indicated when considered by one of ordinary skill in the art. Unless expressly specified otherwise, all of the numerical ranges, amounts, values and percentages such as those for quantities of materials, durations of time, temperatures, operating conditions, ratios of amounts, and the likes thereof disclosed herein should be understood as modified in all instances by the terms “about,” “approximately” or “substantially.” Accordingly, unless indicated otherwise, the numerical parameters set forth in the present disclosure and attached claims are approximations that can vary. At the very least, each numerical parameter should be construed in light of the number of reported significant digits and by applying ordinary rounding techniques. Ranges are expressed herein as from one endpoint to another endpoint, or as between one endpoint and another endpoint. All ranges disclosed herein are inclusive of the endpoints, unless specified otherwise.

The present disclosure relates generally to a DRAM (dynamic random-access memory) device and an operating method thereof, and particularly to one-time-programming (OTP) memory cells formed from DRAM-based memory cells and an operating method thereof.

DRAM is a type of memory widely adopted throughout the industrial, semiconductor, electronic and consumer markets. The DRAM provides advantages such as fast access speed, simple device structure and low power consumption. Generally, the DRAM belongs to a volatile-type memory in contrast to the non-volatile-type memory, e.g., ROM (read-only memory), and is most often used in devices where instruction codes or data are accessed from or to the DRAM memory cells when these devices are powered-on. However, as new applications emerge, such as artificial intelligence (AI) training models, the amount of processing data, whose contents do not change frequently but need to be rapidly accessed from the DRAM memory cells, has increased in an amazing speed. As such, there is a need to provide a memory device that can support both of the volatile-type and non-volatile-type memory cells in a dynamic manner. To address the abovementioned issues, the present disclosure proposes DRAM-based one-time-programming (OTP) memory cells and an operating (including programming and reading) method for the OTP memory cells. With the proposed OTP memory cells in the existing DRAM device, data can be stored permanently in the OTP memory cells, and therefore non-volatile data can co-exist with the volatile data in the DRAM memory device. For example, data of the training models can be stored permanently in the OTP memory cells while the instruction or other variable data can be stored and overwritten in the conventional DRAM memory cells on demand. Thus, the system performance of the DRAM memory device can be enhanced, and the operation power of the DRAM system can be further reduced.

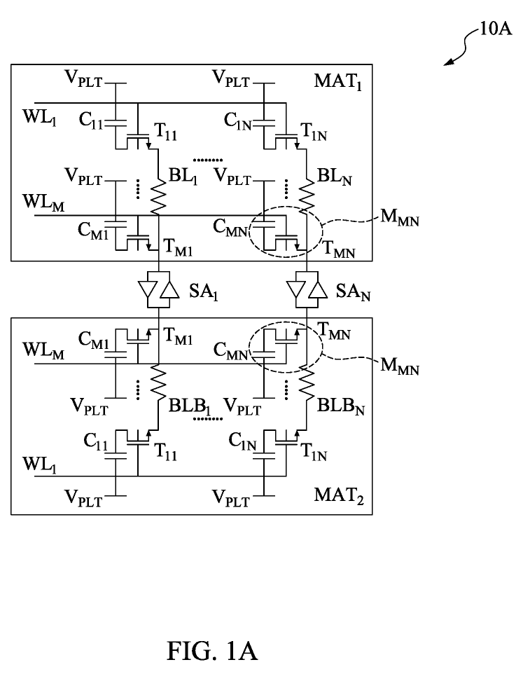

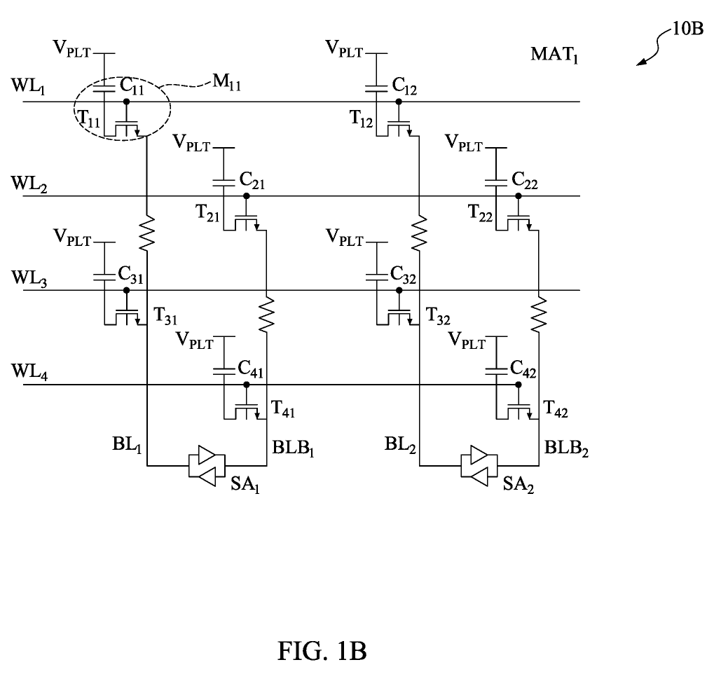

FIG. 1A is a schematic diagram of a memory device 10A, in accordance with various embodiments of the present disclosure. According to some embodiments, the memory device 10A is a DRAM device formed of a plurality of DRAM memory cells. The memory device 10A may include a substrate (not separately shown) on which the DRAM memory cells are formed. The memory device 10A may include multiple arrays of memory cells, e.g., at least one memory bank, in the unit of memory array tile (MAT). FIG. 1A only shows two MATs MAT₁ and MAT₂ for illustrative purposes, but the present disclosure is not limited thereto. The memory device 10A can includes only one or more than two MATs.

According to some embodiments, the MAT MAT₁ or MAT₂ includes a plurality of word lines (WL) WLₘ (m=1, 2,…, M) extending in parallel in a row (horizontal) direction, and a plurality of bit lines (BLₙ) or complementary bit lines (BLBₙ) (n=1, 2,…, N) extending in a column (vertical) direction. The bit line BLₙ and the complementary bit line BLBₙ form a pair of complementary bit lines. The MAT MAT₁ or MAT₂ may further include an array of memory cells Mₘₙ arranged in rows and columns and located on the cross points of the word lines WLₘ and the bit lines BLₙ or complementary bit lines BLBₙ. Each memory cell Mₘₙ comprises a capacitor Cₘₙ and an access transistor Tₘₙ coupled to the capacitor Cₘₙ, wherein the capacitor Cₘₙ is also referred to the storage node Cₘₙ of the memory cells Mₘₙ. According to some embodiments, the quantity of charges stored in the capacitor Cₘₙ represents the log states of the corresponding memory cell Mₘₙ. For example, the capacitor Cₘₙ represents a logic high state (logic “1”) when it is charged, and represents a logic low state (logic “0”) when it is discharged.

According to some embodiments, the memory device 10A further includes a row of sense amplifiers SA₁, SA₂,…SA_{N} configured to read data from or write data to the memory cells Mₘ₁, Mₘ₂,…M_{mN} in the m-th row. For example, each of the row of sense amplifiers SA₁, SA₂,…SA_{N} are configured to receive two complementary input voltages from the corresponding pair of bit lines BLₙ and BLBₙ, perform signal amplification on the received input voltages and output a pair of amplified and complementary logic states as the read-out data of the accessed memory cells Mₘₙ. According to some embodiments, the row of sense amplifiers SA₁, SA₂,…SA_{N} is configured to receive writing voltages corresponding to predetermined write data, and charge or discharge the capacitors Cₘₙ of the corresponding memory cells Mₘₙ according to the writing voltages of the sense amplifiers SA₁, SA₂,…SA_{N}.

The access transistor Tₘₙ is configured to control the writing and reading operations of the capacitor Cₘₙ. The word line WLₘ is configured to control the turn-on or turn-off of the m-th row of the MAT MAT₁ or MAT₂ through transmitting a high-voltage signal or a low-voltage signal, respectively, to the gate of the access transistor Tₘₙ. During the reading operation, for example, the bit line BLₙ and the corresponding complementary bit line BLBₙ of the selected n-th column is configured to be set to a reference voltage, and the access transistor Tₘₙ is turned on through setting a high-voltage signal to a selected m-th row in the selected MAT MAT₁_{,} and the bit line BLₙ of the selected n-th column is configured to receive the voltage variation resulting from the charge state of the capacitor Cₘₙ. At that time, the complementary bit line BLBₙ maintain the reference voltage due to the disablement of the access transistors in MAT MAT₂. Then, the sense amplifier SAₙ is configured to sense the voltage difference between the bit line BLₙ and the complementary bit line BLBₙ, and output the read-out logic states according to the sensed voltage difference. According to some embodiments, the sense amplifier SAₙ is formed of two cross-coupled inverters, and therefore the logic states (or voltages) on the bit line BLₙ and the complementary bit line BLBₙ are complementary to each other after receiving the voltage variation resulting from the capacitor Cₘₙ due to the inverted logic states of the outputs of the two inverters in the sense amplifiers SAₙ.

During the writing operation, for example, the access transistor Tₘₙ is turned on through setting a high-voltage signal to a selected m-th row in the selected MAT MAT₁, and the selected bit line BLₙ, is charged with a writing voltage corresponding to the logic states of the predetermined write data. The capacitor Cₘₙ of the corresponding memory cell Mₘₙ is then written with the writing voltage on the bit line BLₙ. Throughout the present disclosure, the memory cell functioning as volatile DRAM memory cells are referred to as a normal DRAM memory cell, and the reading operation and the writing operation of the normal memory cells of the DRAM device, e.g., the memory device 10A, is collectively referred to as a normal DRAM (access) operation.

According to some embodiments, the capacitor Cₘₙ is formed of two electrodes and an electrically insulating layer sandwiched between the two electrodes. Throughout the present disclosure, a plate electrically coupled to one of the two electrodes and configured to receive a cell plate voltage V_{PLT} is referred to a cell plate or a capacitor node of the capacitor Cₘₙ. The electrically insulating layer may be formed of a dielectric film, such as oxide, nitride, oxynitride, oxides of Lanthanum, Hafnium, and Zirconium, or other suitable dielectric materials. During the reading or writing operation, one of the two electrodes is biased at a cell plate voltage V_{PLT}. During a normal operation, when the access transistor Tₘₙ of the corresponding capacitor Cₘₙ is turned on, the capacitor Cₘₙ will be charged or discharged based on the relative voltages on capacitor Cₘₙ and the corresponding bit line BLₘ or the complementary bit line BLBₘ. According to some embodiments, the cell plate voltage V_{PLT} is kept substantially equal for all of the memory cells Cₘₙ in the memory device 10A to ensure the memory cell Cₘₙ will function properly in a normal reading or writing operation. According to some embodiments, the capacitor Cₘₙ is charged to a logic high state represented by a high voltage, e.g., about one volt and discharged to a logic low state represented by a low voltage, e.g., about zero volts. According to some embodiments, in a normal operation, the cell plate voltage V_{PLT} is set as zero volts or one half of the voltage of the logic high stage, and can be about 0.5 volts. According to some embodiments, in a normal operation, the voltage difference between the two electrodes of the capacitors Cₘₙ is maintained at around 0.5 volts no matter the capacitor Cₘₙ is in a logic high state or a logic low state to reduce the voltage stress caused by the voltage difference applied on the two electrodes. According to some embodiments, the cell plate voltage V_{PLT}, the high voltage and the low voltage for the corresponding logic high state and logic low state are determined such that the voltage difference on two sides of the electrically insulating layer of the capacitor Cₘₙ is lower than the breakdown voltage of the electrically insulating layer to ensure a proper operation of the capacitor Cₘₙ. According to some embodiments, the sense amplifier SAₙ is operated to provide an array voltage V_{ARY}, where the array voltage V_{ARY} is used as a supply voltage for the sense amplifiers SAₙ and set at about 1.2 to about 1.8 volts during a normal operation.

According to some embodiments, when the word line WLₘ is selected to turn on the corresponding row of access transistors Tₘₙ, the word line WLₘ is set at an access voltage Vₚₚ about 2.7 volts. According to some embodiments, when the word line WLₘ is disabled and turns off the corresponding row of access transistors Tₘₙ, the word line WLₘ is set at a voltage Vₖₖ in a range between about -0.3 volts and about 0 volts.

According to some embodiments, referring to FIG. 1A, the row of sense amplifiers SA₁, SA₂,…SA_{N} is arranged between and shared by the two adjacent MATs MAT1 and MAT2, and throughout the present disclosure the configuration of the memory device 10A is referred to as open bit line structure. During operation, only one word line WLₘ in one of the adjacent MATs (for example, MAT₁) is accessed, while all the memory cells on the other word lines of the access MAT (i.e., MAT₁) and all memory cells of the other MAT (for example, MAT₂) are disabled. Among the pair of complementary bit lines of the sense amplifier SAₙ, one bit line of the bit line BLₘ and the complementary bit line BLBₘ, which corresponds to the accessed memory cell Mₘₙ, is configured to sense the voltage of the capacitor Cₘₙ, while the other bit line of the bit line BLₘ and the complementary bit line BLBₘ of the disabled MAT (i.e., MAT₂) is charged with a reference voltage, e.g., one half of the array voltage V_{ARY}, for use of data sensing by the sense amplifier SAₙ.

FIG. 1B is a schematic diagram of a memory device 10B, in accordance with various embodiments of the present disclosure. According to some embodiments, the memory device 10B is a DRAM device formed of a plurality of DRAM memory cells. The memory device 10B may include multiple arrays of memory cells in the unit of memory array tile (MAT). FIG. 1B only shows one MAT MAT₁ for illustrative purposes, but the present disclosure is not limited thereto.

The memory device 10B is similar to the memory device 10A in many aspects, and descriptions of these similar features are not repeated for brevity. The major difference between the memory device 10B and the memory device 10A is the sense amplifiers, e.g., sense amplifiers SA₁, SA₂, are shared by and connected to at least two memory cells Mₘₙ in the same MAT. For example, the memory cells M₁₁ and M₃₁ are connected to the bit line BL₁, while the memory cells M₂₁ and M₄₁ are connected to the complementary bit line BLB₁, where the bit line BL₁ and complementary bit line BLB₁ are complementary bit lines of the sense amplifier SA₁. Similarly, the memory cells M₁₂ and M₃₂ are connected to the bit line BL₂, while the memory cells M₂₂ and M₄₂ are connected to the complementary bit line BLB₂, where the bit line BL₂ and complementary bit line BLB₂ are complementary bit lines of the sense amplifier SA₂. Throughout the present disclosure the configuration of the memory device 10B is referred to as folded bit line structure.

According to some embodiments, more than one memory cells Mₘₙ are electrically coupled to one bit line BL₁ or BL₂ or complementary bit line BLB₁ or BLB₂. During operation, only one word line WLₘ in the MAT (for example, MAT₁) is accessed, while all the memory cells on the other word lines of the access MAT (i.e., MAT₁) are disabled. Among the two complementary bit lines of the sense amplifier SAₙ, one of the bit line BLₘ and the complementary bit line BLBₘ, which corresponds to the accessed memory cell Mₘₙ, is configured to sense the voltage of the capacitor Cₘₙ, while the other bit line of the bit line BLₘ and the complementary bit line BLBₘ, which corresponds to a disabled memory cell Mₘₙ, is charged with a reference voltage, e.g., one half of the array voltage V_{ARY}, for use of data sensing by the sense amplifier SAₙ.

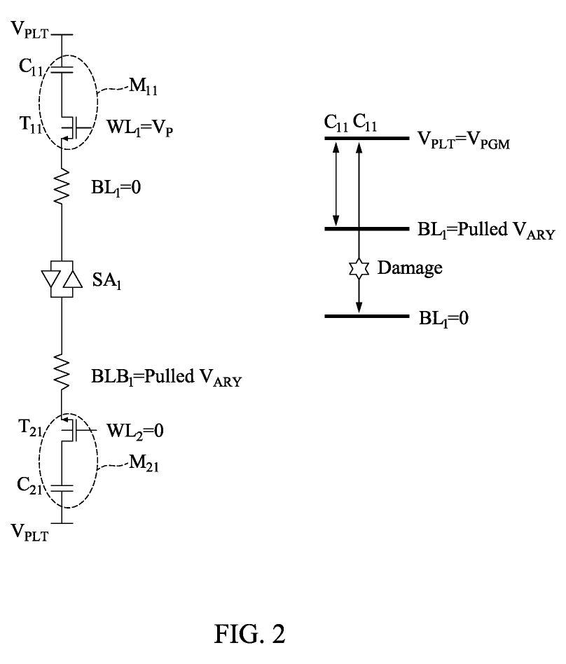

FIG. 2 is a schematic diagram of a programming operation on a memory cell M₁₁, in accordance with some embodiments of the present disclosure. FIG. 2 shows in a left subfigure a memory device 20 including a plurality of memory columns, although only an example memory column is illustrated. The memory column may be formed with an open bit line structure, as shown in FIG. 1A, or formed with a folded bit line structure, as shown in FIG. 1B. The memory column includes a first memory cell M₁₁ in a first row, a second memory cell M₂₁ in a second row, a bit line BL₁ connected to the first memory cell M₁₁, a complementary bit line BLB₁ connected to the second memory cell M₂₁, and a sense amplifier SA₁, wherein the bit line BL₁ and the complementary bit line BLB₁ are the complementary bit lines of the sense amplifier SA₁.

According to some embodiments, a programming operation is performed on the first memory cell M₁₁ to configure the first memory cell M₁₁ as a programmed OTP memory cell. The second memory cell M₂₁ may be a non-programmed OTP memory cell during the programming operation of the first memory cell M₁₁. The capacitor C₂₁ of the second memory cell M₂₁ is not programed (or damaged), and functions similarly to a normal DRAM memory cell. Initially, the access transistor T₁₁ of the first memory cell M₁₁ is turned on by setting the gate voltage at the access voltage V_{PP} through the word line WL₁, while the access transistor T₂₁ of the second memory cell M₂₁ is kept turned off by setting the gate voltage at the about zero volts through the word line WL₂.

The sense amplifier SA₁ is then turned on and written with program data, where the voltage on the bit line (e.g., bit line BL₁) for a programed OTP memory cell is set as logic low state (logic ‘0’), while the voltage on the bit line for a non-programed memory cell is set at the logic high data (logic ‘1’). Thus, the voltages on the bit line BL₁ and the complementary bit line BLB₁ are set as the logic low state and logic high state, respectively, if the OTP memory cell on the bit line BL₁ is to be programed, while the voltages on the bit line BL₁ and the complementary bit line BLB₁ are set as the logic high state and logic low state, respectively, if the OTP memory cell on the bit line BL₁ is to be non-programed.

Subsequently, the array voltage V_{ARY} of the sense amplifier SA₁ is pulled from the normal voltage of about 1.2 to about 1.8 volts used for a normal operation to a higher voltage of about two volts for the programming operation. The pulled array voltage V_{ARY} should be controlled to be lower than the breakdown voltage of the transistors in the sense amplifier SA₁. Subsequently, the cell plate voltages V_{PLT} of the first memory cell M₁₁ and the second memory cell M₂₁ are pulled to a program voltage V_{PGM}, wherein the program voltage V_{PGM} is substantially equal to or greater than twice the array voltage V_{ARY} of the sense amplifier SA₁, for example, to be about 4 volts.

Referring to a right subfigure of FIG. 2, a plot of voltage differences on the electrically insulating layers of the capacitor C₁₁ is shown. Through the abovementioned voltage settings, in a first programming scenario where the memory cell M₁₁ is a programmed memory cell, the two electrodes of the capacitor C₁₁ may provide voltages of V_{PGM} and zero volts, respectively, on two sides of the insulating layer of the capacitor C₁₁. According to some embodiments, the voltage difference between V_{PGM} and zero volts, i.e., the program voltage V_{PGM}, is greater than the breakdown voltage of the electrically insulating layer of the capacitor C₁₁, and thus the program voltage V_{PGM} would cause breakdown of the electrically insulating layer of the capacitor C₁₁. Through the programming operation, a leakage path may be formed in the electrically insulating layer of the capacitor C₁₁ such that the capacitor C₁₁ is unable to retain charges. According to some embodiments, the leakage path formed by the programming operation is stable and permanent, and thus the programmed state of the memory cell M₁₁ can be regarded to be non-volatile.

Conversely, through the abovementioned voltage settings, in a second programming scenario where the memory cell M₁₁ is a non-programmed memory cell, the two electrodes of the capacitor C₁₁ may provide voltages of V_{PGM} and V_{ARY}, respectively, on two sides of the electrically insulating layer of the capacitor C₂₁. According to some embodiments, the voltage difference between V_{PGM} and V_{ARY}, i.e., about two volts, is less than the breakdown voltage of the electrically insulating layer of the capacitor C₁₁, and thus the program voltage V_{PGM} would not cause breakdown of the electrically insulating layer of the capacitor C₁₁. According to some embodiments, the electrically insulating layers of the memory cells Mₘₙ are substantially the same, and therefore the breakdown voltages of the insulating layers in different memory cells are substantially equal. During the programming operation, the electrically insulating layer of the capacitor C₁₁ in a non-programmed memory cell M₁₁ can still function properly such that the capacitor C₁₁ is still able to retain charges just like itself prior to the programming operation.

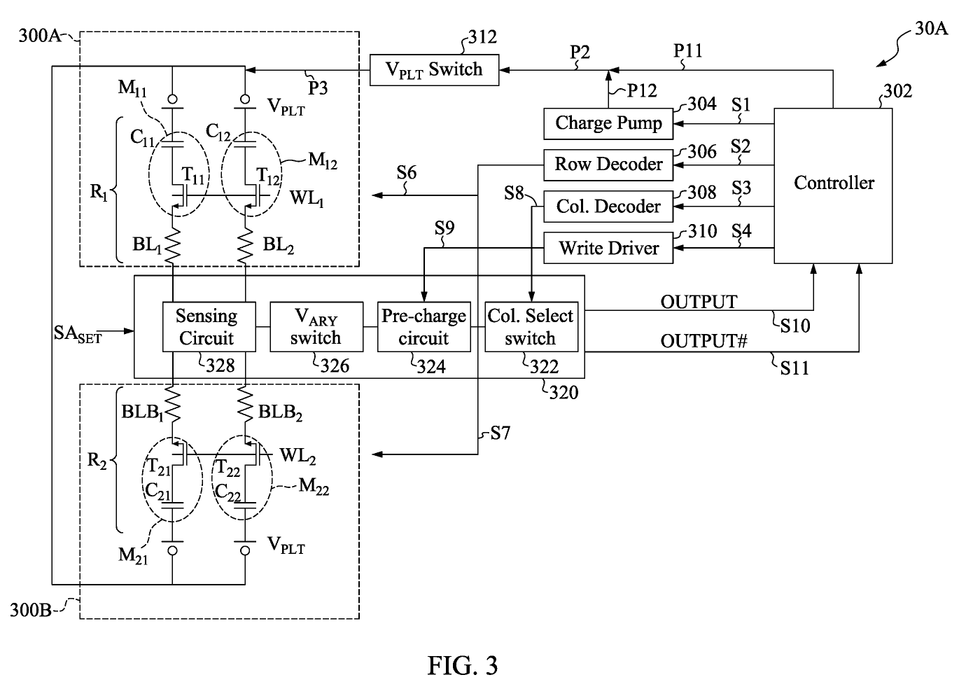

FIG. 3 is a schematic diagram of an OTP memory device 30, in accordance with various embodiments of the present disclosure. The OTP memory device 30 includes a first OTP memory array 300A, a second OTP memory array 300B, a controller 302, a charge pump circuit 304, a row decoder 306, a column decoder 308, a write driver 310, a cell plate voltage (V_{PLT}) switch 312, and a sense amplifier 320. The sense amplifier 320 may include a column select switch 322, a pre-charge circuit 324, an array voltage V_{ARY} switch 326, and a sensing circuit 328. FIG. 3 only shows parts of the OTP memory device 30 for illustrative purposes, but the present disclosure is not limited thereto. More or less elements can be incorporated into or removed from the OTP memory device 30.

According to some embodiments, the first memory cell 300A includes two example columns having respective example memory cell M₁₁ and M₁₂ on an example row R₁ accessed by a word line WL₁, wherein the memory cell M₁₁ includes a capacitor C₁₁ and an access transistor T₁₁ and the memory cell M₁₂ includes a capacitor C₁₂ and an access transistor T₁₂. Likewise, the second memory cell 300B includes two example columns having respective example memory cell M₂₁ and M₂₂ on an example row R₂ accessed by a word line WL₂, wherein the memory cell M₂₁ includes a capacitor C₂₁ and an access transistor T₂₁ and the memory cell M₂₂ includes a capacitor C₂₂ and an access transistor T₂₂. The two columns of the first memory array 300A are accessed by the respective bit lines BL₁ and BL₂, and the two columns of the second memory array 300B are accessed by the respective complementary bit lines BLB₁ and BLB₂.

According to some embodiments, the first memory array 300A or the second memory array 300B may be formed of one or more MATs, or formed of other units of memory, where the first memory array 300A and the second memory array 300B are shown in FIG. 3 for illustrative purposes. According to some embodiments, the first memory array 300A and the second memory array 300B belong to the same MAT or different MATs. The first memory array 300A and the second memory array 300B can be similar to MATs MAT₁ and MAT₂, respectively, shown in FIGS. 1A or 1B, and the details of their descriptions are omitted for brevity. According to some embodiments, the first memory array 300A or the second memory array 300B can be configured as either a volatile (normal) DRAM memory array or a non-volatile (OTP) memory array.

According to some embodiments, the controller 302 is configured to perform transmission and receiving of memory data and control/command signals between the components of the OTP memory device 30. According to some embodiments, the controller 302 is configured to perform a normal operation, including a reading operation and a writing operation, of a normal DRAM memory cell, and perform an OTP operation, including a programming operation and a reading (sensing) operation, of an OTP memory cell. Throughout the present disclosure, the normal operation refers to the reading operation, the writing operation, or both, of a normal DRAM memory cell, and the OTP operation refers to the programming operation, the reading operation, or both, of an OTP memory cell.

According to some embodiments, the controller 302 is configured to supply a cell plate voltage V_{PLT} of about 0.5 volts to the first memory array 300A and the second memory array 300B through a power line P11 for the normal operation of DRAM memory cells. According to some embodiments, the controller 302 is configured to supply a cell plate voltage V_{PLT} of about zero volts to the first memory array 300A and the second memory array 300B through the power line P11 for the OTP reading operation of OTP memory cells. According to some embodiments, a charge pump is a kind of DC-to-DC converter that generally uses capacitors for energetic charge storage to raise or lower an input voltage and generate a desired output voltage with relatively simple circuitry. According to some embodiments, the charge pump circuit 304 is configured to supply the V_{PLT} switch 312 with a cell plate voltage V_{PLT} of about 4 volts as an OTP programming voltage for an OTP programming operation of an OTP memory cell. According to some embodiments, the charge pump circuit 304 is configured to supply the V_{PLT} switch 312 with the pulled array voltage V_{ARY} of about two volts as an OTP reading voltage through a power line P12 for an OTP reading operation. According to some embodiments, the charge pump circuit 304 is replaced with an external power pin, which is configured to receive the predetermined cell plate voltage V_{PLT} as the OTP programming voltage from a power source external to the memory device 30.

According to some embodiments, the controller 302 is configured to transmit a control/command signal OTP_PGM_PLT to the charge pump circuit 304 through a signal line S1 to enable the charge pump circuit 304 for an OTP programming operation. According to some embodiments, the controller 302 is configured to transmit a control/command signal OTP_READ_PLT to the charge pump circuit 304 through the signal line S1 to disable the charge pump circuit 304 for an OTP reading operation. The cell plate voltage V_{PLT} supplied by the controller 302 or the charge pump circuit 304 is transmitted from the power line P11 or P12, through the power line P2 and the V_{PLT} switch 312, and reaches the first memory array 300A and the second memory array 300B via the power line P3.

According to some embodiments, the controller 302 is configured to transmit a row address carried by a row address signal to the row decoder 306 through a signal line S2. According to some embodiments, the row decoder 306 is configured to decode the row address and convert the row address into a row select signal for enabling the selected row in the first memory array 300A or the second memory array 300B. According to some embodiments, the row address signal is transmitted by the controller 302 through the signal line S2, and the row select signal is transmitted from the row decoder 306 to the first memory array 300A and the second memory array 300B through signal lines S6 and S7, respectively, for controlling the memory cells in either a normal operation or an OTP operation.

According to some embodiments, the controller 302 is configured to transmit a column address carried by a column address signal to the column decoder 308 through a signal line S3. According to some embodiments, the column decoder 308 is configured to decode the column address and convert the column address into a column select signal for enabling the selected column in the first memory array 300A or the second memory array 300B. According to some embodiments, the column address signal is transmitted by the controller 302 through the signal line S3, and the column select signal is transmitted from the column decoder 308 to the column select switch 322 in the sense amplifier 320 through a signal line S8, for either a normal operation or an OTP operation. According to some embodiments, the controller 302 is configured to transmit an enable signal SA_{SET} to turn on the sense amplifier 320 prior to a normal operation or an OTP operation of the memory device 30.

According to some embodiments, the controller 302 is configured to transmit write data to the write driver 310 through a signal line S4 for a normal writing operation. According to some embodiments, the controller 302 is configured to transmit a control/command signal OTP_PGM_BL to enable the write driver 310 through the signal line S4 for an OTP programming operation. The controller 302 may provide the write driver 310 with program data, which correspond to the write data to be written into the memory cells, for an OTP programming operation. According to some embodiments, the controller 302 is configured to transmit a control/command signal OTP_READ_BL to the write driver 310 through the signal line S4 for performing an OTP reading operation. The controller 302 may provide the write data to the write driver 310 for sensing the logic states of the OTP memory cells in an OTP reading operation.

The controller 302 may be implemented by hardware, software, firmware, a combination thereof, or the like, and may be formed of a general-purpose computer, a memory controller, a central processing unit (CPU), a graphics processing unit (GPU), an application specific integrated chip (ASIC), a field programmable gate array (FPGA), a digital signal processor (DSP), a microcontroller, or the like.

According to some embodiments, the write driver 310 is configured to cause the complementary bit line pair in the pre-charge circuit 324 to be pulled up to a pre-charge voltage, e.g., one half of array voltage V_{ARY}, through a signal line S9 for a normal operation or an OTP operation. The write driver 310 may provide the write data or program data to the pre-charge circuit 324 through the signal line S9 to thereby enable a normal writing operation, an OTP reading operation, or an OTP programming operation.

According to some embodiments, the array voltage V_{ARY} switch 326 is configured to modulate the voltages of the logic high state data on the bit lines BL₁, BL₂ or the complementary bit lines BLB₁, BLB₂ from a normal voltage, e.g., from about 1.2 volts to about 1.8 volts, to about two volts, to thereby enable an OTP reading operation or an OTP programming operation, and keep the voltages of the logic low state data on the bit lines BL₁, BL₂ or the complementary bit lines BLB₁, BLB₂ as about zero volts. According to some embodiments, the array voltage V_{ARY} switch 326 is implemented by a voltage conversion circuit to convert a voltage from other components of the memory device 30A. According to some embodiments, the array voltage V_{ARY} switch 326 includes a charge pump to pull up the voltages on the bit lines or the complementary bit lines. According to some embodiments, the array voltage V_{ARY} switch 326 received the modulated array voltage V_{ARY} of about two volts from the charge pump 304.

According to some embodiments, the sensing circuit 328 is configured to sense (read) the data of the memory cells in the first memory array 300A or the second memory array 300B for a normal reading operation or an OTP read operation. The sensing circuit 328 may include a number of sense amplifiers (not separately shown), each connected to the corresponding pair of complementary bit line pairs, e.g., the pair of bit lines BL₁ and BLB₁ or the pair of bit lines BL₂ and BLB₂. The outputs of the sensing circuit 328 or the sense amplifier 320 may include a pair of complementary data in a digital form, i.e., a pair of complementary output data bits denoted by labels “output” and “output#”, which are referred to as initial logic states and are transmitted to the controller 302 through signal lines S10 and S11, respectively.

The voltage values discussed with reference to FIGS. 1A, 1B, 2, and other figures in the present disclosure are provided for illustrative purposes. The actual voltage values may be adjusted based on different factor including the circuit design, the manufacturing processes and other requirements.

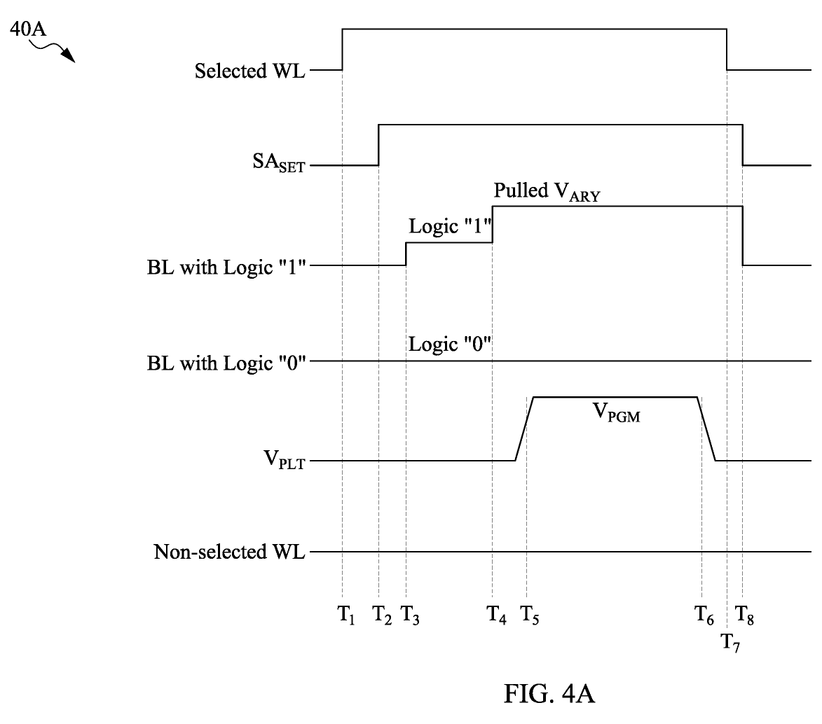

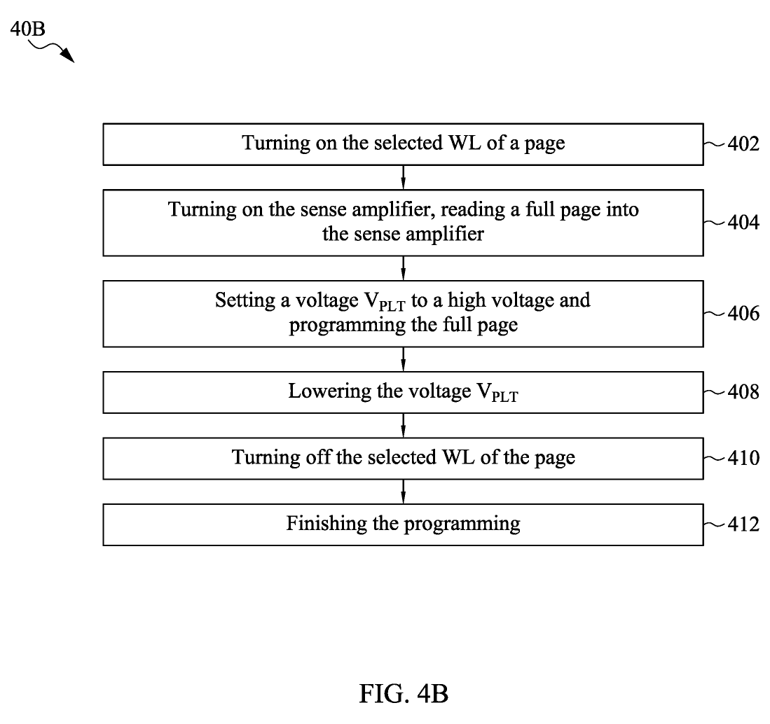

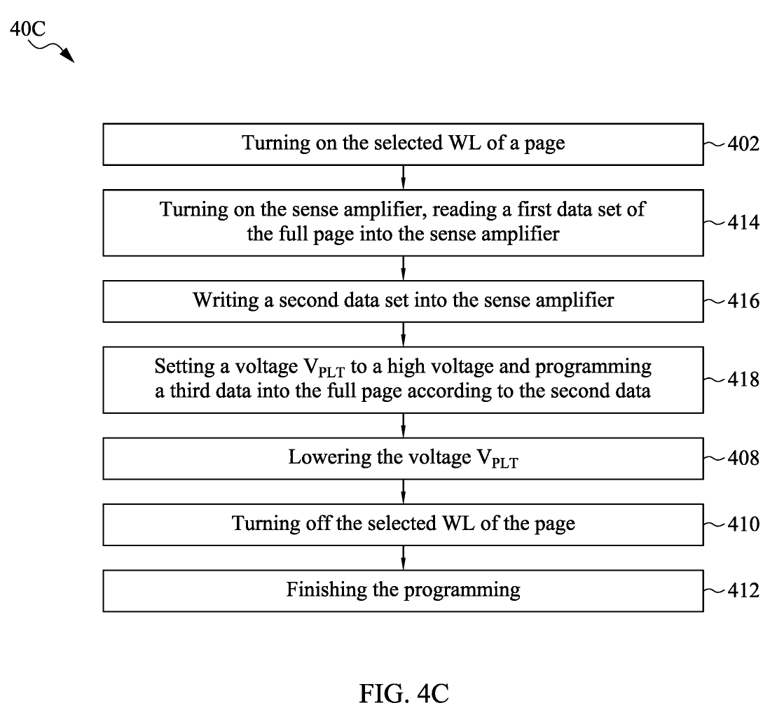

FIG. 4A is a schematic timing diagram of a method 40A of programming a one-time-programming (OTP) memory cell, in accordance with some embodiments of the present disclosure. The method 40A is performed according to the programming operation described with reference to FIG. 2.

At time instant T1, a selected word line (e.g., WL₁) is activated to turned on the access transistors T₁ₙ on the word line WL₁. The voltage on the word line WL₁ may be set as the access voltage V_{PP} about 2.7 volts. Meanwhile, the non-selected word line (e.g., WL₂) is kept deactivated throughout the programming operation of the memory cells on the selected word line by maintaining a low voltage from about -0.3 volts to about zero volts. At time instant T2, the selected sense amplifier SAₙ is activated by an enable signal SA_{SET}.

At time instant T3, program data are read from the memory cells on the selected word line WL₁ or written from the write driver 310 into the sense amplifiers SAₙ, and the voltages on the bit line BL₁ and complementary bit line BLB₁ are pulled to the voltages corresponding to logic high (‘1’) and logic low (‘0’) data, respectively, e.g., from about 1.2 to about 1.8 volts and zero volts, respectively, in the program data. At time instant T4, when the voltage on the bit line BL₁ is logic high, the voltage on the bit line BL₁ is pulled to about 2 volts as the pulled V_{ARY} by the array voltage V_{ARY} switch. Conversely, when the voltage on the bit line BL1 is logic low at the time instant T4, the voltage on the bit line BL₁ is kept about zero volts.

At time instant T5, the cell plate voltage V_{PLT} is pulled to the program voltage V_{PGM} (e.g., about 4 volts) to cause breakdown of the electrically insulating layer of the programmed memory cell M₁₁. For the memory cell corresponding to the bit line BL₁ with logic low, the electrically insulating layer of the memory cell is breakdown and the memory cell is OTP programmed as the programmed memory cell. Meanwhile, for the memory cell corresponding to the bit line BL₁ with logic high, due to the presence of the pulled array voltage V_{ARY}, the program voltage V_{PGM} will not cause a large voltage difference across the electrically insulating layer of the memory cell corresponding to the bit line BL₁ with logic high. Therefore, the memory cell corresponding to the bit line BL₁ with logic high will not be OTP programmed.. In addition, for non-selected memory cell, such as M₂₁, the non-selected word line WL₂ is disable, and the electrically insulating layer of the unselected memory cell will not encounter the voltage difference and not damage

At time instant T6, after the programming operation is completed, the cell plate voltage V_{PLT} is lowered to a low voltage, e.g., a voltage for a normal operation, e.g., about 0.5 volts or zero volts. At time instant T7, the selected word line (e.g., WL₁) is turned off or disabled and lowered to a voltage between about -0.3 volts and about zero volts. At time instant T8, the sense amplifier SA₁ is turned off, and the voltage on the bit line (e.g., BL₁) associated with the programmed memory cell (e.g., M₁₁) is also pulled down to about zero volts.

In present disclosure, the selected word line WL keeps active during the OTP programming operation. According to some embodiments, the selected word line WL is enabled before the enable signal (SA_{SET}) of sense amplifier. According to some embodiments, the selected word line WL is enabled before the voltage pull-up of the plate voltage V_{PLT}. According to some embodiments, the sense amplifier is enabled after the enablement of selected word line WL and before the pull-up of the plate voltage V_{PLT}. According to some embodiments, the written data of all memory cells in the selected word line WL, which may be referred as the full-page data, may be loaded and stored in the sense amplifier before performing the OTP program operation. In response to the pull-up of the plate voltage V_{PLT}, the full-page data of the selected word line WL can be OTP programmed with the full page at the same time. Therefore, the OTP programming speed can be further enhanced.

FIG. 4B is a schematic flowchart showing a method 40B of programming an OTP memory cell, in accordance with various embodiments of the present disclosure. It should be understood that additional steps can be provided before, during, and after the steps shown in FIG. 4B, and some of the steps described below can be replaced or eliminated in other embodiments of the method 40B. According to some embodiments, the method 40B is used to convert the DRAM memory cells into DRAM-based OTP memory cells with identical data contents from those in the written DRAM memory cells.

At step 402, a selected word line of a page is turned on. Throughout the present disclosure, a page refers to a number of data bits loaded into a row of sense amplifiers SAₙ when such row is activated by a word line at the same time, e.g., a typical page may be formed of one or more MATs and may form a row of 4K data bits, although other lengths of a page may be alternatively defined.

At step 404, the sense amplifiers SAₙ are turned on or activated to read the program data of a full page from the memory cells on the selected word line into the sense amplifiers SAₙ.

At step 406, a cell plate voltage V_{PLT} is set to a high voltage, e.g., a program voltage V_{PGM}, and the memory cells of the full page are programmed. According to some embodiments, since the cell plate voltages V_{PLT} for each memory cell Mₘₙ of the same page are set to the high voltage V_{PGM}, the programming of the full page can be completed at substantially the same time. The programming efficiency can be greatly improved.

At step 408, after the programming operation, the cell plate voltage V_{PLT} is lowered to a normal voltage of about 0.5 volts or zero volts used in a normal operation.

At step 410, the selected word line is turned off, e.g., the voltage of the selected word line of the page is lowered to be from about -0.3 volts to about zero volts, to deactivate or disable the selected word line. At step 412, the programming operation is finished.

FIG. 4C is a schematic flowchart showing a method 40C of programming an OTP memory cell, in accordance with various embodiments of the present disclosure. It should be understood that additional steps can be provided before, during, and after the steps shown in FIG. 4C, and some of the steps described below can be replaced or eliminated in other embodiments of the method 40C. According to some embodiments, the method 40C is used to convert the DRAM memory cells into DRAM-based OTP memory cells with different data contents from those in the written DRAM memory cells.

At step 402, a selected word line of a page is turned on.

At step 414, the sense amplifier SAₙ is turned on or activated to read first data set of a full page from the memory cells on the selected word line into the sense amplifier SAₙ. At step 416, a second data set is written, e.g., from the write driver 310, into the sense amplifiers SAₙ. According to some embodiments, the second data set is different from the first data set.

At step 418, a cell plate voltage V_{PLT} is set to a high voltage, e.g., a program voltage V_{PGM}, and a third data set are programmed into the full page according to the second data set. The third data set is generated according to the second data set stored in the sense amplifiers SAₙ.

At step 408, after the programming operation, the cell plate voltage V_{PLT} is lowered to a normal voltage of about 0.5 volts or zero volts used in a normal operation.

At step 410, the selected word line is turned off, e.g., the voltage of the selected word line of the page is lowered to be from about -0.3 volts to about zero volts, to deactivate or disable the selected word line. At step 412, the programming operation is finished.

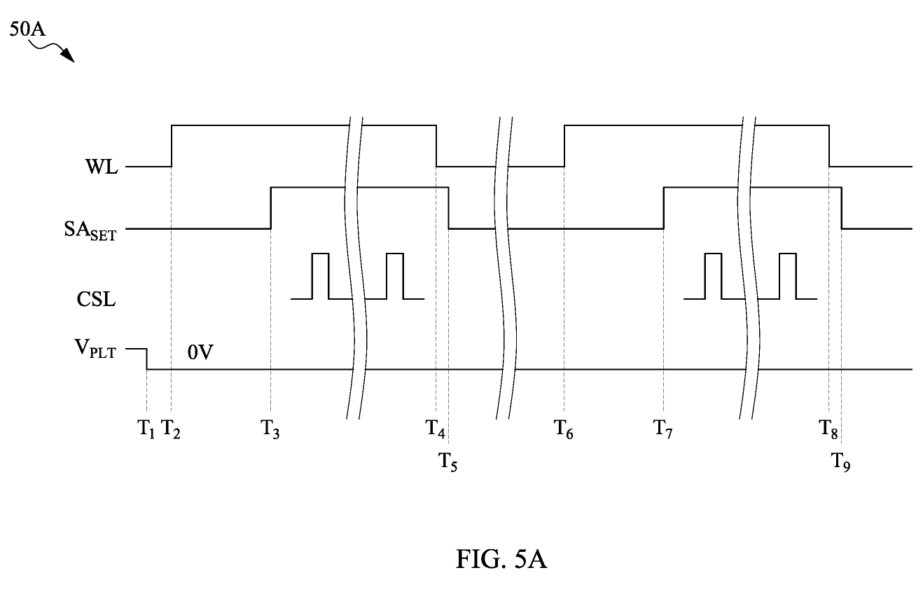

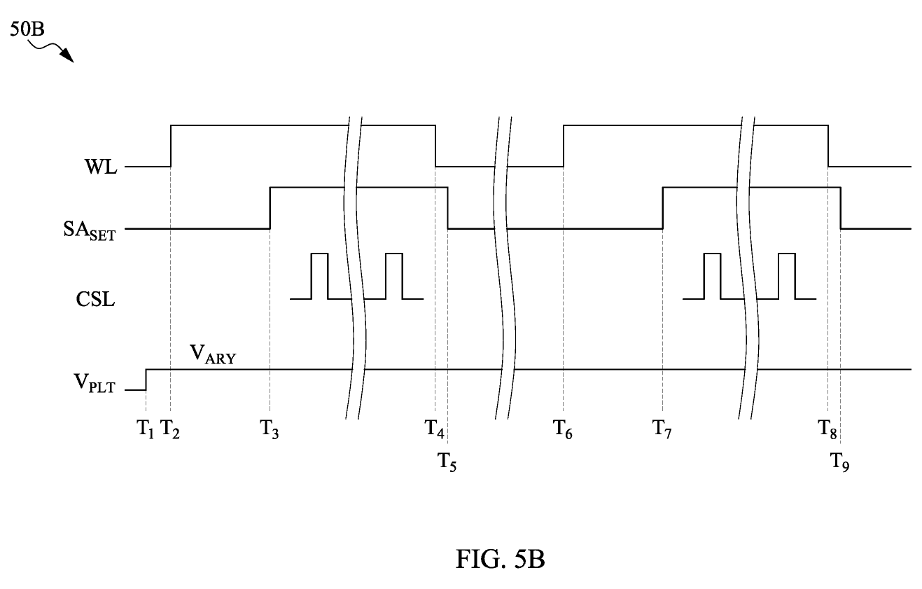

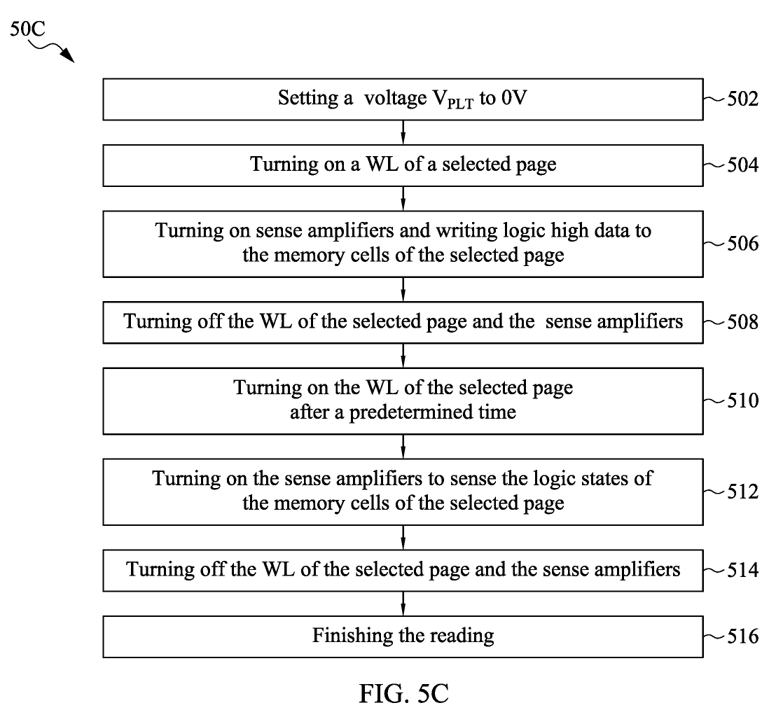

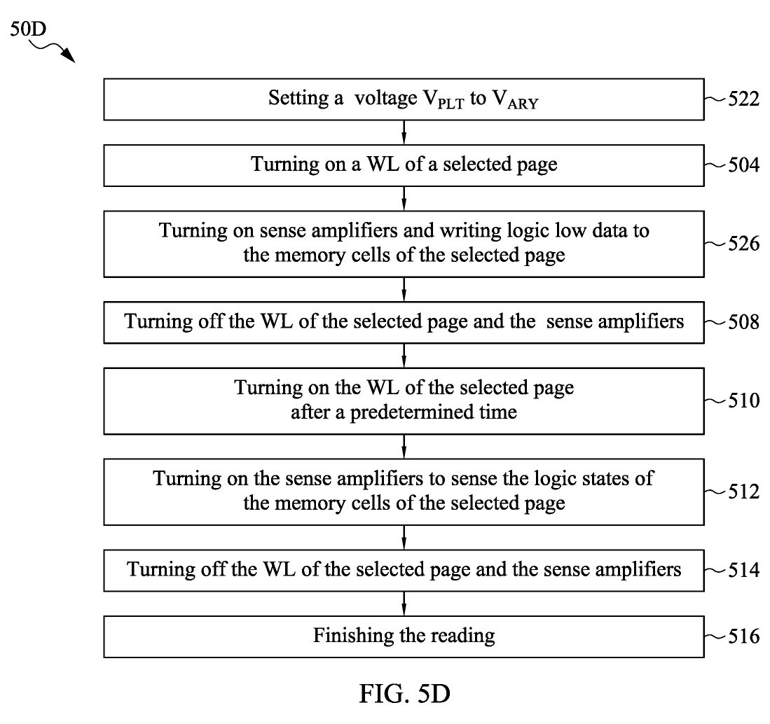

FIG. 5A is a schematic timing diagram of a method 50A of reading one-time-programming (OTP) memory cells, in accordance with various embodiments of the present disclosure.

At time instant T1, the cell plate voltage V_{PLT} is set at or lowered to the low voltage of about zero volts. At time instant T2, a selected word line WLₘ of a page is activated to turn on the access transistors Tₘₙ on the word line WLₘ. The voltage on the selected word line WLₘ may be set as the access voltage V_{PP}. Meanwhile, the non-selected word lines are kept deactivated throughout the reading operation of the selected word line WLₘ by maintaining a low voltage, .e.g., from about -0.3 volts to about zero volts.

At time instant T3, the sense amplifiers SAₙ are turned on or activated by an enable signal SA_{SET}. Each sense amplifier SAₙ on the respective column is written at time instants of the clock of a column select signal CSL successively. Write data of logic high (‘1’), e.g., with a high voltage of about 1.2 volts to about 1.8 volts, are written into the memory cells Mₘₙ of the selected page. This way, during the activation time period of the sense amplifiers SAₙ between time instants T3 and T4, the selected memory cells Mₘₙ can be written with the logic high data successively via the selected word line WLₘ and the selected column.

At time instant T4, after the program data are written to the memory cells Mₘₙ, the selected word line WLₘ is turned off or disabled. At time instant T5, the sense amplifiers SAₙ are turned off.

At time instant T6, the selected word line of the page is activated to turn on the access transistors Tₘₙ on the word line after a predetermined waiting time T_{R} defined as T_{R} = T6-T4. At time instant T7, the sense amplifiers SAₙ are turned on or activated by the enable signal SA_{SET}. Data sensed by each sense amplifier SAₙ on the respective column is read out at time instants of the clock of the column select signal CSL successively. The OTP data stored in the memory cells Mₘₙ of the selected page are sensed and read out by the sense amplifiers SAₙ. This way, the data of the selected memory cells Mₘₙ can be read out successively via the selected word line WLₘ and the selected column.

According to some embodiments, data or charges stored in the storage node Cₘₙ (capacitor) of the non-OTP programmed memory cell Mₘₙ can last for a predetermined period of data retention time. The charges may gradually leak to the substrate of the memory device. After the period of data retention time the charges in the memory cell will be lost and the logic state is read as a logic low bit (‘0’) no matter which data state was initially stored therein. Further, for an OTP programmed memory cell Mₘₙ, the charges will leak through the leakage path within a data retention time much shorter than that of the non-OTP programmed memory cell Mₘₙ. Based on the above observation, the data bits of the OTP programmed memory cell Mₘₙ.and the non-OTP programmed memory cell Mₘₙ.can be differentiated through their different lengths of data (charge) retention time periods. For example, the data retention time of the OTP programmed memory cell Mₘₙ.is much less than about 64 milliseconds (ms), e.g., in a range of several microseconds (µs), while the data retention time, of the non-OTP programmed memory cell Mₘₙ.is substantially equal to or greater than about 64 ms. The predetermined waiting time T_{R} is thus set as a waiting time in a time range shorter than the data retention time of the non-programmed memory cells and longer than the data retention time of the programmed memory cells. Alternatively, the predetermined waiting time T_{R} is the data retention time of a normal DRAM memory cell before it is subjected to an OTP programming operation. Thus, the predetermined waiting time T_{R} is set as substantially equal to or greater than about 64 ms. According to some embodiments, the predetermined waiting time T_{R} is set longer than 32 ms but shorter than 100 ms. Once the logic high state data are written to both the OTP programmed and non-OTP programmed memory cells and after the waiting time T_{R}, the non-OTP programmed memory cell Mₘₙ. would keep the charges in the capacitor Cₘₙ, while the OTP programmed memory cell Mₘₙ. would lose the charges in the capacitor Cₘₙ, In other words, the memory cell Mₘₙ with a readout data bit of logic low state is determined to be a OTP programmed memory cell, and the memory cell Mₘₙ with a readout data bit of logic high state is determined to be a non-OTP programmed memory cell.

At time instant T8, after the written data of the memory cells Mₘₙ are read out, the selected word line WLₘ is turned off or disabled. At time instant T9, the sense amplifiers SAₙ are turned off.

FIG. 5B is a schematic timing diagram of a method 50B of reading one-time-programming (OTP) memory cells, in accordance with various embodiments of the present disclosure.

At time instant T1, the cell plate voltage V_{PLT} is set at or pulled to the high voltage of the array voltage V_{ARY} of about 1.2 volts to about 1.8 volts. At time instant T2, a selected word line WLₘ of a page is activated to turn on the access transistors Tₘₙ on the word line WLₘ. The voltage on the selected word line WLₘ may be set as the access voltage V_{PP}. Meanwhile, the non-selected word lines are kept deactivated throughout the reading operation of the selected word line WLₘ by maintaining a low voltage, e.g., from about -0.3 volts to about zero volts.

At time instant T3, the selected sense amplifiers SAₙ are turned on or activated by an enable signal SA_{SET}. Each sense amplifier SAₙ on the respective column is written at time instants of the clocks of a column select signal CSL successively. Write data of logic low states (‘0’), e.g., with a low voltage of about zeros volts, are written into the memory cells Mₘₙ of the selected page. This way, during the activation time period of the sense amplifiers SAₙ between time instants T3 and T4, the selected memory cells Mₘₙ can be written with the logic low state data successively via the selected word line WLₘ and the selected column.

At time instant T4, after the write data are written to the memory cells Mₘₙ, the selected word line WLₘ is turned off or disabled. At time instant T5, the sense amplifiers SAₙ are turned off.

At time instant T6, the selected word line of the page is activated to turn on the access transistors Tₘₙ on the word line after a predetermined waiting time T_{R} defined as T_{R} = T6-T4. At time instant T7, the sense amplifiers SAₙ are turned on or activated by the enable signal SA_{SET}. Data sensed by each sense amplifier SAₙ on the respective column is activated read out at time instants of the clocks of the column select signal CSL successively. The OTP data stored in the memory cells Mₘₙ of the selected page are sensed and read out by the sense amplifier SAₙ. This way, the data of the selected memory cells Mₘₙ can be read out successively via the selected word line WLₘ and the selected column.

As discussed previously, the data bits of the OTP programmed memory cell Mₘₙ.and the non-OTP programmed memory cell Mₘₙ.can be differentiated through their different lengths of data (charge) retention time periods. The waiting time T_{R} is thus configured to be shorter than the data retention time of the non-OTP programmed memory cells and longer than the data retention time of the OTP programmed memory cells. However, different from the OTP data sensing scheme shown with reference to FIG. 5A, once the logic low state data are written to both the OTP programmed and non-OTP programmed memory cells and after the waiting time T_{R}, the OTP data sensing scheme discussed with reference to FIG. 5B will cause the non-OTP programmed memory cell Mₘₙ. to keep the logic low state (i.e., the low voltage of about zero volts) of the capacitor Cₘₙ, and cause the OTP programmed memory cell Mₘₙ or the sensing bit line BLₙ to be charged with the array voltage V_{ARY}, In other words, the data sensing result with reference to FIG. 5B, which is opposite to that with reference to FIG. 5A, will determine the memory cell Mₘₙ with a readout data bit of logic high state to be a OTP programmed memory cell, and determine the memory cell Mₘₙ with a readout data bit of logic low state to be a non-OTP programmed memory cell.

At time instant T8, after the write data of the memory cells Mₘₙ are read out, the selected word line WLₘ is turned off or disabled. At time instant T9, the sense amplifiers SAₙ are turned off.

FIG. 5C is a schematic flowchart showing a method 50C of reading an OTP memory cell, in accordance with various embodiments of the present disclosure. The method 50C is performed with reference to the method described with reference to FIG. 5A. It should be understood that additional steps can be provided before, during, and after the steps shown in FIG. 5C, and some of the steps described below can be replaced or eliminated in other embodiments of the method 50C.

At step 502, the cell plate voltage V_{PLT} is set to a low voltage of about zero volts. At step 504, a selected word line of a selected page is turned on.

At step 506, the sense amplifiers SAₙ are turned on or activated, and the write data with logic high state (‘1’), e.g., with a high voltage of about one volt, of a full page are written into memory cells Mₘₙ of the selected page through the sense amplifiers SAₙ.

At step 508, the selected word line is turned off, e.g., the voltage of the selected word line of the page is lowered to be from about -0.3 volts to about zero volts, to deactivate or disable the selected word line. The sense amplifiers are also turned off.

At step 510, the selected word line of the selected page is turned on after a predetermined time, e.g., the predetermined waiting time T_{R}. At step 512, the sense amplifiers are turned on to sense the logic states of the memory cells of the selected page.

After the data sensing operation is completed, at step 514, the selected word line is turned off, e.g., the voltage of the selected word line of the page is lowered to be from about -0.3 volts to about zero volts, to deactivate or disable the selected word line. The sense amplifiers SAₙ are also turned off. At step 516, the data reading operation is finished.

FIG. 5D is a schematic flowchart showing a method 50D of reading an OTP memory cell, in accordance with various embodiments of the present disclosure. The method 50D is performed with reference to the method described with reference to FIG. 5B. It should be understood that additional steps can be provided before, during, and after the steps shown in FIG. 5D, and some of the steps described below can be replaced or eliminated in other embodiments of the method 50D.

At step 522, the cell plate voltage V_{PLT} is set to a high voltage, e.g., the array voltage V_{ARY}, e.g., about 1.2 volts or 1.8 volts. At step 504, a selected word line of a selected page is turned on.

At step 526, the sense amplifiers SAₙ are turned on or activated, and the write data with logic low state (‘0’), e.g., with a low voltage of about zero volts, of a full page are written into memory cells Mₘₙ of the selected page through the sense amplifiers SAₙ.

At step 508, the selected word line is turned off, e.g., the voltage of the selected word line of the page is lowered to be from about -0.3 volts to about zero volts, to deactivate or disable the selected word line. The sense amplifiers are also turned off.

At step 510, the selected word line of the selected page is turned on after a predetermined time, e.g., the predetermined waiting time T_{R}. At step 512, the sense amplifiers are turned on to sense the logic states of the memory cells of the selected page.

After the data sensing operation is completed, at step 514, the selected word line is turned off, e.g., the voltage of the selected word line of the page is lowered to be from about -0.3 volts to about zero volts, to deactivate or disable the selected word line. The sense amplifiers are also turned off. At step 516, the data reading operation is finished.

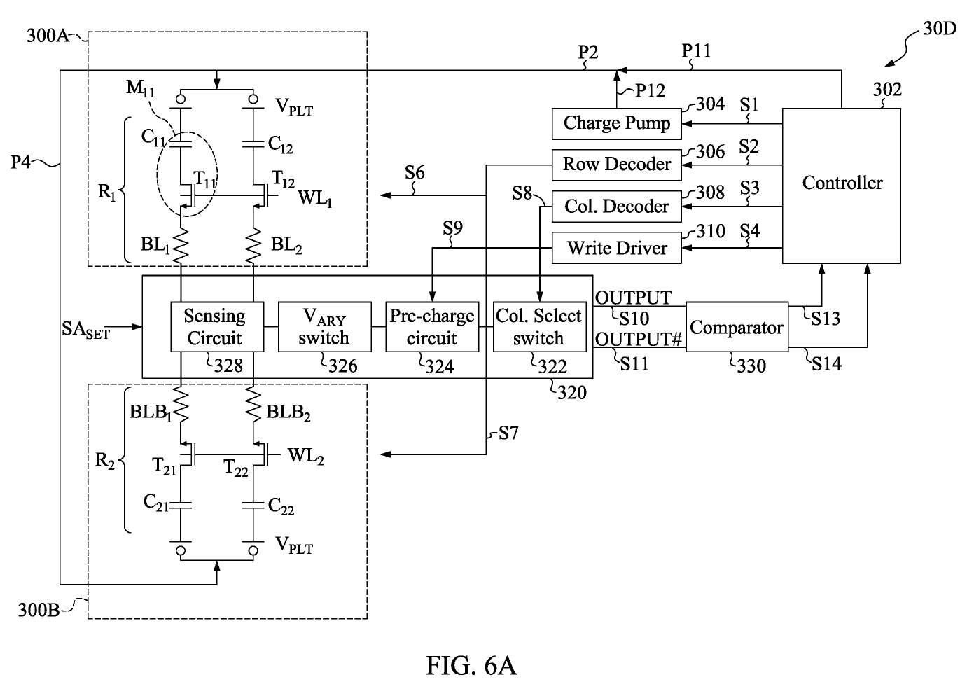

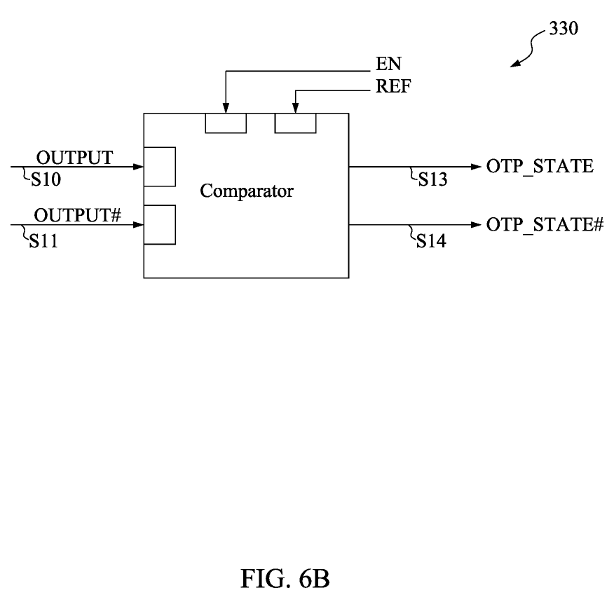

FIG. 6A is a schematic diagram of an OTP memory device 60, in accordance with various embodiments of the present disclosure. The OTP memory device 60 is similar to the OTP memory device 30 in many aspects, and descriptions of these similar aspects are not repeated for brevity. The OTP memory device 60 is different from the OTP memory device 30 in that the OTP memory device 60 does not include the cell plate voltage V_{PLT} switch 312 and the array voltage V_{ARY} switch 326. According to some embodiments, the cell plate voltage V_{PLT} switch 312 is omitted from the OTP memory device 60 such that all of the memory rows in the OTP memory device 60 are shorted together for simplifying the complexity of the control circuitry. According to some embodiments, since the voltage amplification circuitry can be implemented in other components of the OTP memory device 60, such as the charge pump 304 or the write driver 310, the functional block of the array voltage V_{ARY} switch 326 can omitted from the OTP memory device 60 but the function of voltage amplification provided by the array voltage V_{ARY} switch 326 can still be implemented in the OTP memory device 60 and can be supported by other blocks of the OTP memory device 60.

According to some embodiments, the OTP memory device 60 further includes a comparator 330 between the sense amplifier 320 and the controller 302. The comparator 330 is configured to receive the output data bits “output” and “output#” (i.e., initial logic states) of the sensing circuit 328 in the sense amplifier 320 in a normal reading operation or an OTP reading operation, and provide logic states of modulated OTP output data bits denoted by labels “OTP_STATE” and “OTP_STATE#” (which are referred to as final logic states) to the controller 302.

FIG. 6B is a schematic diagram of the comparator 330 of the OTP memory device 60A, in accordance with various embodiments of the present disclosure. The comparator 330 includes two input ports configured to receive the data bits on the signal lines S10 and S11, i.e., the complementary data bits of “output” and “output#” provided by the sense amplifier 320. The comparator 330 further includes two output ports configured to provide the controller 302 with the logic states of the modulated complementary OTP data bits “OTP_STATE” and “OTP_STATE#” for the normal reading operation or the OTP reading operation through signal lines S13 and 14, respectively.

Moreover, the comparator 330 may further include an enable signal port configured to receive an enable signal “EN” from the controller 302 to turn on the comparator 330. The OTP memory device 60 may be configured to perform a normal DRAM operation in the absence of the enable signal “EN.” According to some embodiments, the comparator 330 also include a reference signal port configured to receive a reference signal “REF” from the controller 302 for performing data comparison. According to some embodiments, the reference signal “REF” includes the value of a bit line pre-charge voltage V_{BLP}, which is a value of about one half of the logic high stage (‘1’), e.g., about 0.5 volts.

As discussed previously, the data bits of the OTP programmed memory cell Mₘₙ and the non-OTP programmed memory cell Mₘₙ can be differentiated through their different lengths of data (charge) retention time periods. The waiting time T_{R} is thus configured to be shorter than the data retention time of the non-OTP programmed memory cells and longer than the data retention time of the OTP programmed memory cells. The data reading operation for the OTP memory cells using the comparator 330 can be performed follow the reading operation discussed with reference to FIGS. 5A or 5B, where write data of logic high state data or logic low state data are written to both the programmed and non-programmed memory cells. After the waiting time T_{R}, the OTP data sensing scheme discussed with reference to FIG. 5A will determine the memory cell Mₘₙ with a readout data bit of logic low state to be an OTP programmed memory cell, and determine the memory cell Mₘₙ with a readout data bit of logic high state to be a non-OTP programmed memory cell. Alternatively, the OTP data sensing scheme discussed with reference to FIG. 5B will determine the memory cell Mₘₙ with a readout data bit of logic high state to be an OTP programmed memory cell, and determine the memory cell Mₘₙ with a readout data bit of logic low state to be a non-OTP programmed memory cell.

Based on the above principle, the OTP reading operation incorporating the comparator 330 can be performed by comparing one or both of the pair of complementary output data bits “output” and “output#” with the reference signal “REF” and provide the logic states of the pair of modulated OTP output data bits “OTP_STATE” and “OTP_STATE#” on the signal line S13 and S14. According to some embodiments, the OTP programmed memory cell and the non-OTP programmed memory cell are mapped to the logic high state and the logic low state of the memory cell, respectively, based on some design requirements. Alternatively, the OTP programmed memory cell and the non-OTP programmed memory cell are mapped to the logic low state and the logic high state of the memory cell, respectively, based on other design requirements

According to some embodiments, the logic states of the modulated OTP data bits “OTP_STATE” and “OTP_STATE#” are detected based on direct estimation of the data retention time of the memory cells of interest. As discussed previously, the data bits of the OTP programmed memory cell Mₘₙ.and the non-OTP programmed memory cell Mₘₙ.can be differentiated through their different lengths of data (charge) retention time periods. Thus, the writing data of logic high state data or logic low state data are written to both the programmed and non-programmed memory cells. The comparator 330 is configured to estimate the data retention time of the memory cells, which is the voltage falling time from the logic high state (e.g., at the voltage of about one volt) to the logic low state (e.g., at the voltage of about zero volts). The data included in the reference signal “REF” is set as a time period, e.g., about 64 ms, between the data retention time of the non-programmed memory cell and the data retention time of the programmed memory cell. If the estimated voltage falling time is substantially equal to or greater than the reference signal “REF,” then the memory cell is determined to be a non-OTP programmed memory cell. Conversely, if the estimated voltage falling time is less than the reference signal “REF,” then the memory cell is determined to be an OTP programmed memory cell.

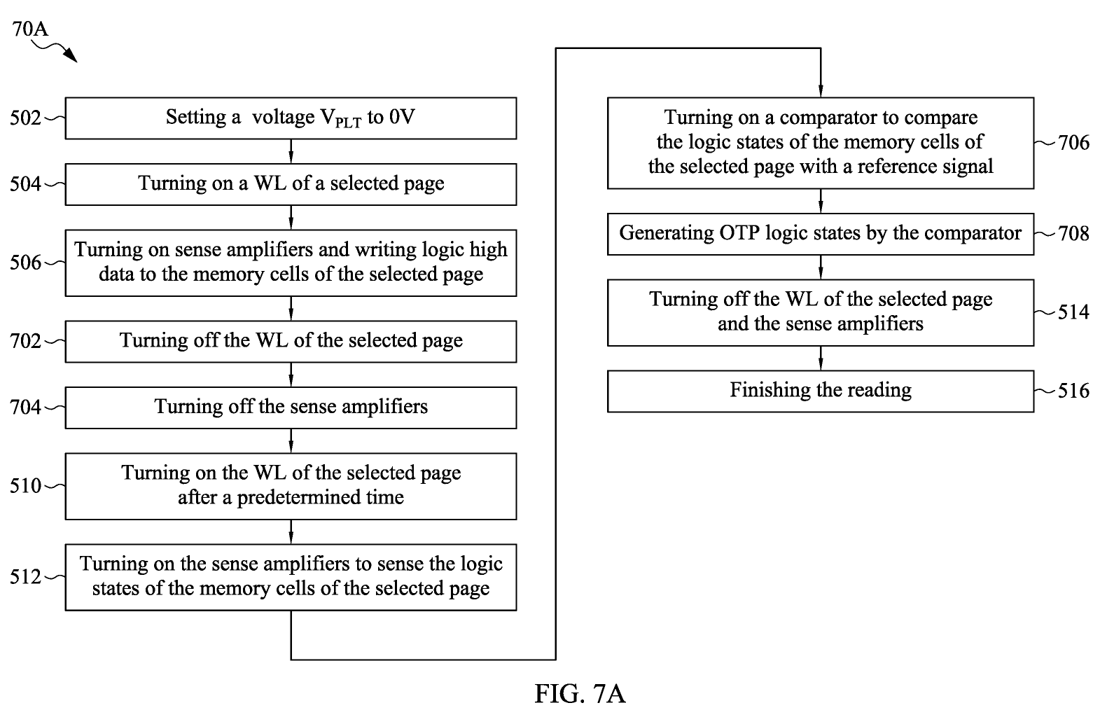

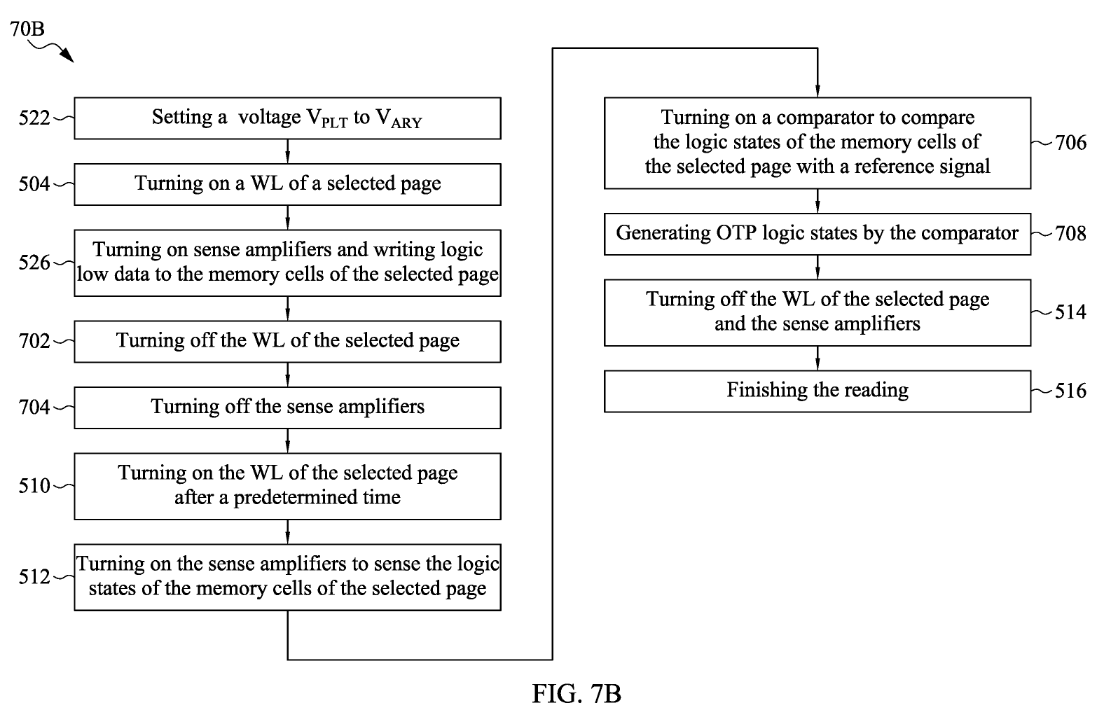

FIG. 7A is a schematic flowchart showing a method 70A of reading an OTP memory cell, in accordance with various embodiments of the present disclosure. The method 70A is performed with reference to the method described with reference to FIGS. 5A and 5C, and the memory device 60 shown FIG. 6A. It should be understood that additional steps can be provided before, during, and after the steps shown in FIG. 7A, and some of the steps described below can be replaced or eliminated in other embodiments of the method 70A.

At step 502, the cell plate voltage V_{PLT} is set to a low voltage of about zero volts. At step 504, a selected word line of a selected page is turned on. At step 506, the sense amplifiers SAₙ are turned on or activated, and the writing data with logic high state (‘1’), e.g., with a high voltage of about one volt, of a full page are written into memory cells Mₘₙ of the selected page through the sense amplifiers SAₙ.

At step 702, the selected word line is turned off, e.g., the voltage of the selected word line of the page is lowered to be from about -0.3 volts to about zero volts, to deactivate or disable the selected word line. At step 704, the sense amplifiers SAₙ are turned off. Steps 702 and 704 may correspond to step 508 shown in FIG. 5C.

At step 510, the selected word line of the selected page is turned on after a predetermined time, e.g., the predetermined waiting time T_{R}. At step 512, the sense amplifiers are turned on to sense the logic states of the memory cells of the selected page.

After the data sensing operation is performed, at step 706, a comparator is turned on to compare the logic states of the memory cells of the selected page with a reference signal. At step 708, OTP logic states are generated by the comparator.

At step 514, the selected word line is turned off, e.g., the voltage of the selected word line of the page is lowered to be from about -0.3 volts to about zero volts, to deactivate or disable the selected word line. The sense amplifiers are also turned off. At step 516, the data reading operation is finished.

FIG. 7B is a schematic flowchart showing a method 70B of reading an OTP memory cell, in accordance with various embodiments of the present disclosure. The method 70B is performed with reference to the method described with reference to FIGS. 5B and 5D, and the memory device 60 shown FIG. 6A. It should be understood that additional steps can be provided before, during, and after the steps shown in FIG. 7B, and some of the steps described below can be replaced or eliminated in other embodiments of the method 70B.

At step 522, the cell plate voltage V_{PLT} is set to a high voltage of the array voltage V_{ARY}, e.g., about 1.2 volts to 1.8 volts. At step 504, a selected word line of a selected page is turned on. At step 526, the sense amplifiers SAₙ are turned on or activated, and the writing data with logic low state (‘0’), e.g., with a low voltage of about zero volts, of a full page are written into memory cells Mₘₙ of the selected page through the sense amplifiers SAₙ.

The steps 702, 704, 510, 512, 706, 708, 514 and 516 are similar to those steps shown in FIG. 7A, and descriptions of these steps are omitted for brevity.

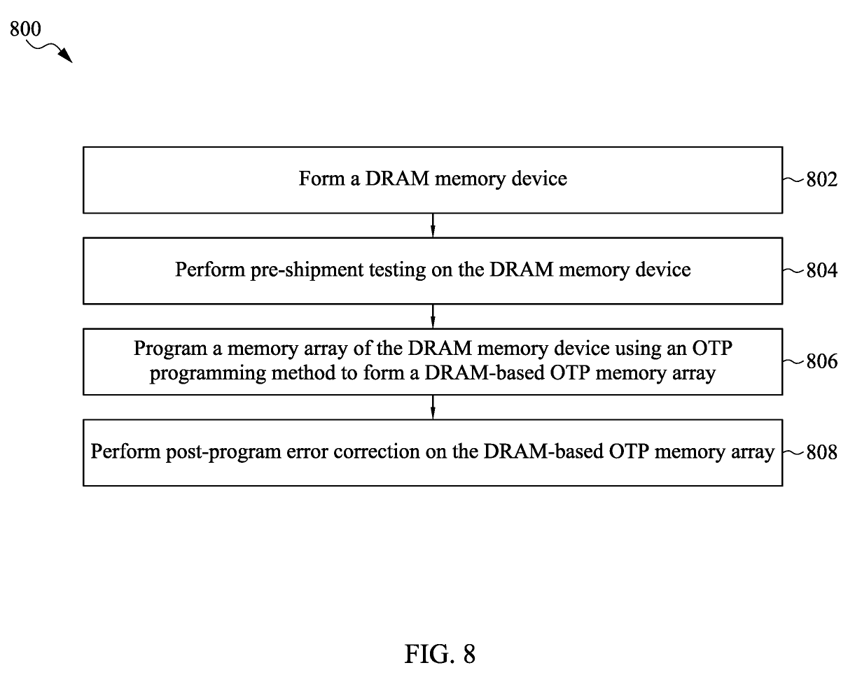

FIG. 8 is a schematic flowchart showing a method 800 of forming and testing a memory device, in accordance with various embodiments of the present disclosure. It should be understood that additional steps can be provided before, during, and after the steps shown in FIG. 8, and some of the steps described below can be replaced or eliminated in other embodiments of the method 800.

At step 802, a DRAM memory device is formed. According to some embodiments, the DRAM memory device includes normal DRAM memory cells and/or DRAM-based OTP memory cells.

At step 804, a pre-shipment testing operation is performed on the DRAM memory device. The pre-shipment testing operation is based on normal DRAM functions, such as a normal reading operation and a normal writing operation. According to some embodiments, an error correction operation is performed on the defective memory cell or memory array. According to some embodiments, defective rows or columns of the DRAM memory device are repaired or replaced by replacement rows or columns based on the repairing techniques known in the art used for repairing normal DRAM memory cells.

At step 806, after shipment or sale of the DRAM memory device, a programming operation is performed by a user on a memory array of the DRAM memory device using an OTP programming operation discussed herein to form a DRAM-based OTP memory array.

At step 808, a post-program error correction operation is performed on the DRAM-based OTP memory array. According to some embodiments, a program-verify testing process is performed prior to the post-program error correction operation to determine which OTP memory cell(s) is defective. According to some embodiments, defective rows or columns of the OTP memory device are repaired based on the repairing techniques known in the art used for repairing normal DRAM memory cells.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages as those of the embodiments introduced herein. Those skilled in the art should also realize that such equivalent constructions do not depart from the spirit and scope of the present disclosure, and that they may make various changes, substitutions, and alterations to the embodiments disclosed herein without departing from the spirit and scope of the present disclosure.

What is claimed is:

1. A programming method of a DRAM (dynamic random-access memory)-based one time programming (OTP) memory device, comprising:
turning on a selected word line (WL) of a selected page;
turning on a sensing circuit to sense a first data set in the selected page into the sensing circuit;
setting a cell plate voltage (V_{PLT}) to a high voltage and programming the selected page;
lowering the V_{PLT}; and
turning off the selected WL of the selected page.

2. The programming method of a DRAM-based OTP memory device according to claim 1, further comprising writing a second data set into the sensing circuit before setting the V_{PLT} to the high voltage.

3. The programming method of a DRAM-based OTP memory device according to claim 2, wherein during the setting of the V_{PLT} to the high voltage, further comprising programming an entirety of the selected page with a third data set according to the second data set.

4. The programming method of a DRAM-based OTP memory device according to claim 1, wherein the selected WL of the selected page is turned on before the setting the V_{PLT} to the high voltage.

5. The programming method of a DRAM-based OTP memory device according to claim 1, wherein the turning on of the sensing circuit is performed after the turning on of the selected WL and before the setting the V_{PLT} to the high voltage.

6. The programming method of a DRAM-based OTP memory device according to claim 1, wherein the programming of the selected page is performed such that all data in the selected page are programmed at the same time.

7. The programming method of a DRAM-based OTP memory device according to claim 1, the first data set including a logic high data corresponding to a first bit line, wherein the programming method further comprises:
setting a voltage of the first bit line to a pulled array voltage (pulled V_{ARY}) before the setting of the V_{PLT} to the high voltage.

8. The programming method of a DRAM-based OTP memory device according to claim 1, the first data set including a logic low data corresponding to a second bit line, wherein the programming method further comprises:
setting a voltage of the second bit line to a low voltage before the setting of the V_{PLT} to the high voltage.

9. A reading method of a DRAM-based one time programming (OTP) memory device, comprising:
setting a plate voltage (V_{PLT}) to a first voltage;
turning on a selected word line (WL) of a selected page;
turning on a sensing circuit;
writing a first logic state into a plurality of memory cells of the selected page, wherein the first logic state is corresponding to the first voltage;
turning off the selected WL of the selected page and the sensing circuit;
turning on the selected WL of the selected page after a predetermined time; and
turning on the sensing circuit to sense at least one second logic state of the memory cell in the plurality of memory cells in the selected page.

10. The reading method of a DRAM-based OTP memory device according to claim 9 wherein the first voltage is a low voltage, and the first logic state is a high state.

11. The reading method of a DRAM-based OTP memory device according to claim 9 wherein the first voltage is a high voltage, and the first logic state is a low state.

12. The reading method of a DRAM-based OTP memory device according to claim 9 further comprising turning on a comparator to compare the at least one second logic state of the memory cell in the plurality of memory cells of the selected page with a reference signal.

13. The reading method of a DRAM-based OTP memory device according to claim 12, further comprising generating at least one OTP logic state of the memory cell in the plurality of memory cells of the selected page according to the at least one second logic state and the reference signal by the comparator.

14. The reading method of a DRAM-based OTP memory device according to claim 9, wherein the setting of the V_{PLT} at the first voltage is performed before the turning on the selected WL of the selected page.

15. The reading method of a DRAM-based OTP memory device according to claim 9, wherein the predetermined time is a retention time of a normal DRAM memory cell before OTP programming.

16. The reading method of a DRAM-based OTP memory device according to claim 9, wherein the predetermined time is substantially equal to or longer than about 64ms.

17. The reading method of a DRAM-based OTP memory device according to claim 9, further comprising turning on several columns of the plurality of memory cells by column select signals during the writing of the first logic state into the plurality of memory cells of the selected page.

18. The reading method of a DRAM-based OTP memory device according to claim 9, further comprising turning on several columns of the plurality of memory cells by column select signals during the turning on of the sensing circuit to sense the plurality of the second logic states of the plurality of memory cells in the selected page.

19. A testing and correction method of a DRAM-based one time programming (OTP) memory device, wherein the DRAM-based OTP memory device is programmed by an OTP programming operation including:
turning on a selected word line (WL) of a selected page;
turning on a sensing circuit to sense a first data set in the selected page into the sensing circuit;,
setting a cell plate voltage (V_{PLT}) to a high voltage and programming the selected page;
lowering the V_{PLT}; and
turning off the selected WL of the selected page,
wherein the testing and correction method of the DRAM-based OTP memory device comprises:
performing a pre-shipment testing before the OTP programming operation of the DRAM-based OTP memory device based on a normal DRAM function test.

20. The testing and correction method of a DRAM-based OTP memory device according to claim 19, further comprising a post-programming error correction after the programming operation of the DRAM-based OTP memory device based on an error correction code operation or an addressing remapping operation.
